(19) United States
(12) Patent Application Publication
(10) Pub. No.: US 2021/0398961 A1
(43) Pub. Date: Dec. 23, 2021

(54) High Density Optical Interconnection Assembly

(71) Applicant: Aayuna Inc., Allentown, PA (US)

(72) Inventors: Kalpendu Shastri, Orefield, PA (US); Anujit Shastri, San Francisco, CA (US); Soham Pathak, Allentown, PA (US); Bipin D. Dama, Bridgewater, NJ (US); Rao Yelamarty, Allentown, PA (US)

(73) Assignee: Aayuna Inc., Allentown, PA (US)

(21) Appl. No.: 17/296,744

(22) PCT Filed: Dec. 1, 2019
(86) PCT No.: PCT/US2019/063899

§ 371 Date: May 25, 2021

Related U.S. Application Data
(60) Provisional application No. 62/774,443, filed on Dec. 3, 2018.

(51) Int. Cl. H01L 25/16; G02B 6/122; H01L 23/498

(52) U.S. Cl. CPC H01L 25/167; H01L 23/49827; G02B 6/122

(57) ABSTRACT

A high density opto-electronic interconnection arrangement includes an interposer disposed over the substrate and used to provide a high density electrical connection to a group of electrical ICs flip-chip mounted on the substrate. A set of optical ICs are disposed over and attached to the electrical ICs, where the positioning of the optical IC on the top of the stack eliminates the need to form vias through the thickness of the optical substrate. Thus, a relatively thick optical IC component may be used, providing a stable optical axis and improving alignment and coupling of optical signal paths.

### CROSS-REFERENCE TO RELATED APPLICATIONS

This application claims the benefit of U.S. Provisional Application No. 62/774,443, filed Dec. 3, 2018 and herein incorporated by reference.

### TECHNICAL FIELD

The present invention relates to interconnect technology for arrangements including multiple electrical and optical integrated circuits and, more particularly, to a specific configuration of electrical and optical integrated circuits with respect to interposer elements that provides high density, high speed electrical connections that are able to operate in a compatible manner with high speed optical circuits.

### BACKGROUND OF THE INVENTION

The next generation high performance opto-electronic systems are known to need about a ten-fold increase in interconnection bandwidth about every four years. Against this increase in demand are the requirements to maintain cost, power and space as minimal as possible. Moore's Law and the newer 2.5D/3D IC packaging technologies have enabled a number of integration advances sufficient to address most of the interconnection bandwidth concerns. However, this improvement has been achieved by requiring the implementation of additional assembly and packaging complexity, necessarily increasing the cost of the final component, and often with high power demands and/or the need for relatively large-sized configurations for all of the requisite electrical and optical interconnections.

While advances in silicon photonics are expected to play a key role in addressing some of these goals, inasmuch as it allows for integration to keep pace with Moore's Law and minimizes some costs by taking advantage of well-known IC fabrication techniques, there remain many concerns regarding optimum configurations for packaging these interconnection components, particularly configurations scalable with proposed large numbers of high bandwidth interconnects for next generation systems.

### SUMMARY OF THE INVENTION

The needs remaining in the prior art are addressed by the present invention, which relates to interconnect technology for arrangements including multiple electrical and optical integrated circuits and, more particularly, to a specific configuration of electrical and optical integrated circuits with respect to interposer elements that provide high density, high speed electrical connections that are able to operate in a compatible manner with high speed optical circuits.

In accordance with the principles of the present invention, an interposer element is included in an interconnection assembly arrangement with multiple electrical integrated circuits (ICs) positioned in flip-chip connection form on the interposer element, with separate optical integrated circuits positioned on (and electrically connected to) each electrical IC than possible with prior art arrangements that locate the optical IC on the interposer.

This atypical “stack” of interposer/electrical IC/optical IC has been found to allow for a higher density interconnection to be provided between the interposer and the electrical IC. Additionally, inasmuch as there is no longer any need to form vias through the optical IC (as was common in the prior art), the optical substrate may be substantially thicker than prior art arrangements. The use of a thicker optical substrate minimizes any kind of bending or warping that may take place, creating an improved optical reference plane that remains fixed and provides improved alignment with an attached fiber array component.

Various embodiments may comprise an arrangement that utilizes a single interposer element that essentially covers the surface of a substrate that provides electrical connections to additional circuitry, with multiple “mini-stacks” of an electrical IC/optical IC disposed at defined locations on the interposer (referred to at times as a “common” interposer, or single interposer configuration). Other embodiments may be configured to utilize separate interposer elements with each mini-stack (referred to at times as a “modular” interposer configuration). The interposer itself may comprise glass, silicon, or any other suitable material through which vias may be formed and disposed in high density arrangements, where for the purposes of the present invention, “high density” may be defined as requiring a spacing of only tens of microns (perhaps even in the range of 5-15 μm) between adjacent vias.

The electrical connections between the electrical IC and the interposer, as well as between the electrical IC and the optical IC, preferably comprise high-speed electrical connectors such as, but not limited to, copper pillars, micro-bumps, or the like.

An exemplary embodiment of the present invention takes the form of a high density opto-electronic interconnection arrangement comprising a substrate formed to support a plurality of electrical signal paths, terminating as electrical surface contacts at defined locations on the substrate, an interposer disposed over the substrate and formed to include a plurality of a through-vias that create an electrical connection to the electrical surface contacts of the substrate, a plurality of electrical ICs mounted in flip-chip form on the interposer, and a plurality of optical ICs mounted in flip-chip form on the plurality of electrical ICs to provide a one-to-one association between the plurality of electrical ICs and the plurality of optical ICs.

Other and further embodiments and aspects of the invention will become apparent during the course of the following discussion and by reference to the accompanying drawings.

### BRIEF DESCRIPTION OF THE DRAWINGS

Referring now to the drawings, where like numerals represent like parts in several views:

FIG. 1 is a cut-away side view of a high density interconnection arrangement formed in accordance with the present invention, and based upon the use of a common interposer component;

FIG. 2 is a top view of the high density interconnection arrangement of FIG. 1;

FIG. 3 is an enlargement of a portion of the side view of FIG. 1;

FIG. 4 is a cut-away side view of an alternative embodiment of the present invention, in this case utilizing a plurality of modular interposer components;

FIG. 5 is a top view of the embodiment of the present invention as illustrated in FIG. 4; and

FIG. 6 is a cut-away side view of a particular configuration of the embodiment of FIG. 4, utilizing a multi-layer connection assembly between each electrical IC and its associated (modular) interposer.

### DETAILED DESCRIPTION

As integrated circuit (IC) technology continues to scale to smaller critical dimensions, it is increasingly difficult for existing interconnection technologies to provide suitable communication characteristics, such as high bandwidth, lower power, improved reliability, and low cost. Continued research is directed to interconnect technology solutions that enable the provision of high density, high performance systems. While optical connections and signal paths (typically in the form of optical fibers) are a cost-effective solution to communicate modest amounts of data in certain portions of systems (such as between racks and, in some cases, between boards within a rack), it is often difficult to scale these photonic components to meet the bandwidth, size, and power requirements of input/output (I/O) interfaces for future chips.

By combining electrical I/O interconnections with optical connection configurations, it is possible to improve the final interconnection assembly. Indeed, the ability to use individually optimized technologies in the formation of separate electrical and optical ICs allows for each improvements to be made in both the electrical and optical domains and thus take advantage of advances in both technologies.

As will be explained in detail below, the present invention provides such a hybrid electrical/optical interconnection configuration that is optimized by controlling the arrangement of the components such that each optical IC is disposed on its associated electrical IC, with the group of electrical ICs thereafter connected to additional electrical circuitry through a high-density interposer connection configuration.

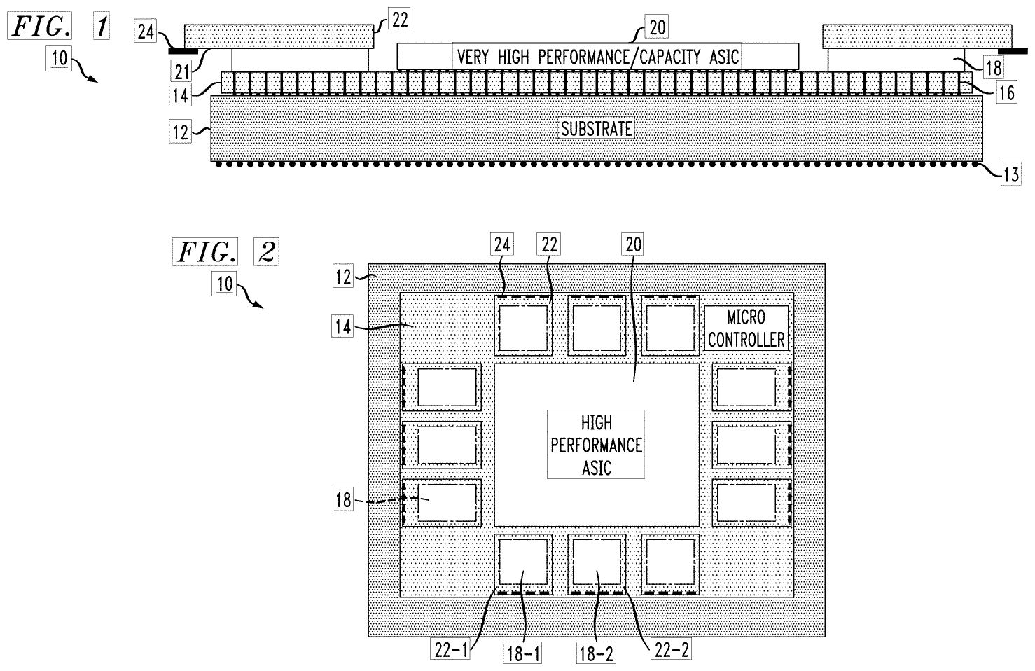

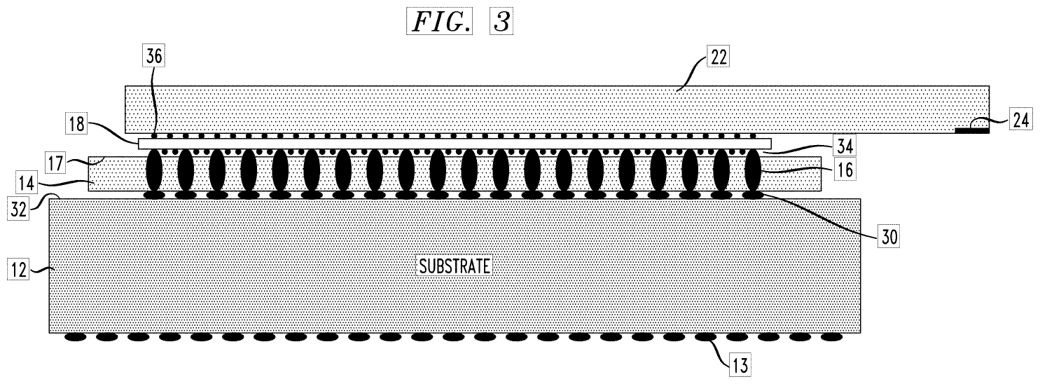

FIG. 1 is a side view of an exemplary high density interconnection configuration 10 formed in accordance with the principles of the present invention, where FIG. 2 is a top view of the same configuration and FIG. 3 is an enlarged view of a portion of the side view of FIG. 1. Referring to both FIGS. 1 and 2, configuration 10 is shown as comprising a substrate 12 with an interposer 14 disposed over substrate 12. Interposer 14 may be made of silicon, a glass, a ceramic, and/or an organic material having a coefficient of thermal expansion (CTE) that is similar to silicon. For example, interposer 14 may comprise borosilicate glass. This feature may provide the thermo-mechanical latitude to use shorter and higher-density micro-bumps on chips, and also allow the chips to be bonded very close together. In accordance with the principles of the present invention, interposer 14 is formed to include a large number of through-vias 16, with the spacing between adjacent vias 16 on the order of tens of microns or so (perhaps even slightly less than 10 μm), thus forming a “high density” interconnection structure.

Continuing with the description of high density interconnection configuration 10, a plurality of electrical ICs 18 is disposed at designated locations on interposer 14. The specific configuration of FIG. 1 also includes a separate electrical IC 20 that may take the form of a high density switch/router, application-specific IC (ASIC), or other high performance electrical IC that is intended to communicate with the plurality of electrical ICs 18. High performance IC 20 may also require a large number of connections is and preferably flip-chip mounted on interposer 14 in the same manner as electrical ICs 18. While not specifically shown in FIGS. 1 and 2, the electrical signal paths between high performance IC 20 and the plurality of electrical ICs 18 is provided by specific interconnections defined within substrate 12 and interposer 14. These connections are typically provided by one or more redistribution layers (RDLs) forming an insulative substrate (such as substrate 12), with electrical signal paths disposed on the individual RDLs and vias, as appropriate to complete the “wiring” connections between the individual ICS (here, between the plurality of electrical ICs 18 and high performance IC 20).

In further accordance with the present invention, a set of optical ICs 22 is disposed over the set of electrical ICs 18 in a one-to-one manner (i.e., a first optical IC 22-1 is disposed over a first electrical IC 18-1, a second optical IC 22-2 is disposed over a second electrical IC 18-2, and so on, forming a “stack” of components that communicate with one another). The top view of FIG. 2 illustrates the location of these optical ICs 22 as the top element of each individual stack, with the underlying electrical IC 18 indicated by the dotted outline in each stack. Fiber array connectors 24 are shown along the outer edge of each optical IC 22, and positioned in this exemplary embodiment on a lower surface 21 of optical IC 22 (as discussed below, this lower surface 21 is defined as the “top”, active surface of optical IC 22). Inasmuch as no electrical signal paths are required to pass through the thickness of optical IC 22 (in contrast to prior art configurations), optical IC 22 may be formed on a relatively thick substrate, minimizing (if not eliminating) the possibility for warpage of optical IC 22. It is to be understood that the illustrations contained in FIGS. 1-6 are not to scale, either in the absolute or when viewing one component in relation to another. For example, an exemplary electrical IC 18 may have a thickness on the order of 100 μm or so, and its associated optical IC 22 may have a thickness on the order of 400-750 μm (or more).

Further, as best shown in the side view of FIG. 1, optical ICs 22 are specifically sized to overhang side edges 15 of interposer 14. The overhang regions allow for connectors 24 to be positioned well beyond the limits of interposer 14 and therefore allow for ease of connectivity between external fiber ribbons and fiber array connectors 24 formed on each optical IC 22.

As mentioned above, FIG. 3 is an enlarged view of a portion of high density interconnection configuration 10, particularly illustrating exemplary electrical connection arrangements among the elements forming a “stack”. It is to be noted that these are exemplary only and that other types of connections are possible.

In accordance with the principles of the present invention, electrical IC 18 is bonded “face down” (i.e., active side down) onto interposer 14 (also referred to at times as a “flip-chip” connection). As shown, interposer 14 includes through-vias 16 that terminate at an associated number of metal contacts 30 on a top surface 32 of substrate 12. In current and future applications, this arrangement is contemplated as being a “high density” interconnection, with a minimal pitch between adjacent through-vias 16 (e.g., on the order of tens of microns, perhaps even slightly less than 10 μm). With further reference to FIG. 3, a first set of electrical connectors 34 is disposed on a top surface 17 of interposer 14, providing a set of electrical signal path connections to electrical IC 18. A second set of electrical connectors 36 is disposed between electrical IC 18 and optical IC 22. These electrical connectors 34, 36 may comprise copper pillars, micro-bumps, or any other suitable type of connector structure suitable for high-density, high-speed configurations.

In many system assemblies, the arrangement as shown in FIGS. 1-3 is itself further mounted on and electrically connected to a main circuit board (not shown). A plurality of electrical contact pads 13 (which may take the form of a ball grid array (BGA)) is shown in FIG. 1 as formed across a bottom surface 15 of substrate 12, and used to provide the electrical connection between interconnection configuration 10 and the remainder of the assembly. BGA connection 13 is typically used to bring power and ground connections to configuration 10, as well as provide a path for low speed signals, and exhibits a lower density of connections than those discussed above.

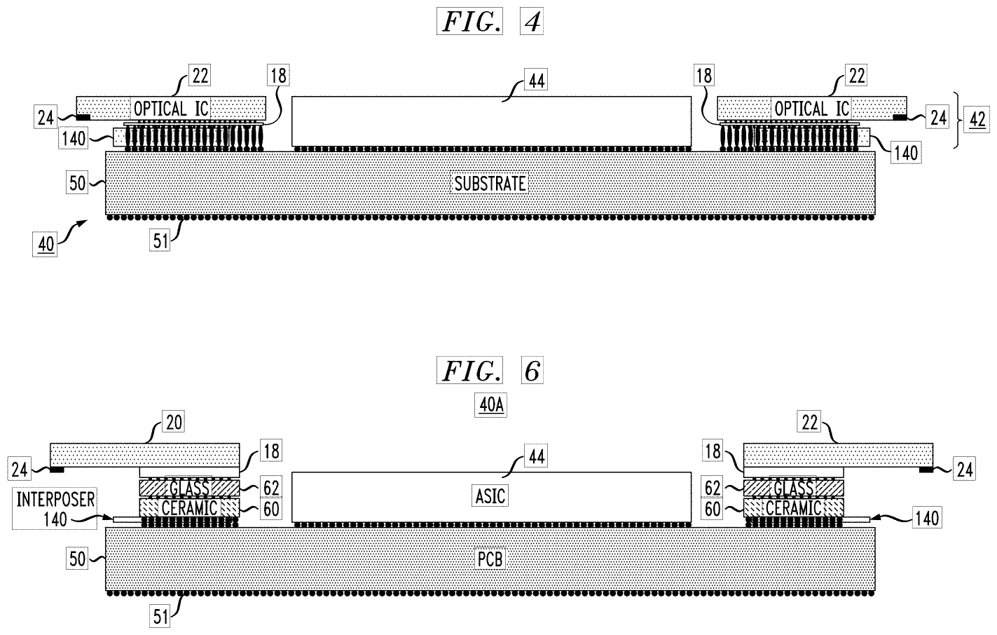

An alternative embodiment of the present invention provides a somewhat more modular approach in the assembly of the high density interconnection configuration. While maintaining the same organization in terms of positioning an optical IC over an electrical IC in a one-to-one configuration, the arrangement as shown in FIGS. 4-6 utilizes individual stack assemblies, each having its own interposer component 140, instead of a single, common interposer 14 as described above. This alternative embodiment also referenced as using “modular” interposers.

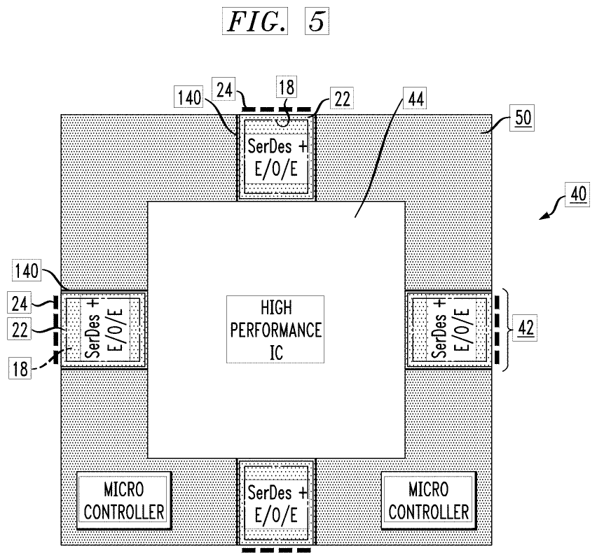

FIG. 4 is side view of a modular interconnection configuration 40 formed in accordance with this particular embodiment of the present invention, with a top view shown in FIG. 5. An exemplary stack 42 of components is shown as positioned adjacent to a centrally-located high-performance integrated circuit 44. In contrast to the previously-described embodiment, high performance IC 44 is directly flip-chip bonded on a substrate 50, since a high density connection is able to be directly formed using copper pillars, micro-bumps, or the like. A connection configuration, shown as BGA connection 51, is as formed on the underside of substrate 50 and used to provide a large number of signal paths between substrate 50 (with internal RDLs) and a higher-level assembly arrangement.

Turning to the description of an individual stack 42, each comprises an interposer 140, electrical IC 18, and optical IC 22. Electrical ICs 18 and optical ICs 22 are essentially the same (or similar) as the elements as discussed above in association with FIGS. 1-3, with the same high density connection arrangements (e.g., copper pillars, micro-bumps, or the like). A fiber array interconnection configuration 24 is formed as discussed above on the “bottom” (i.e., active) surface of each optical IC 22.

Referring to the top view of FIG. 5, it is evident that each stack 42 is disposed at defined locations across the surface of substrate 50. As before, sets of RDLs are used within substrate 50 to provide electrical connection between each stack 42 and high performance IC 44.

In another arrangement of this exemplary embodiment, each stack 42 may be supplemented to include a compliant (i.e., flexible) member that is able to accommodate mechanical stresses associated with the various CTEs of the different components within stack 42. Moreover, it is contemplated that a preferred type of compliant electrical connection is configured as utilizing a type of “plug-in”-compatible interconnect, allowing for relatively quick and easy insertion and removal of various stacks 42 with respect to substrate 50. FIG. 6 illustrates one possible arrangement of this embodiment, with a ceramic base layer 60 and a glass layer 62.

The foregoing description is intended to enable any person skilled in the art to make and use the disclosure, and is provided in the context of a particular application and its requirements. Moreover, the foregoing descriptions of embodiments of the present disclosure have been presented for purposes of illustration and description only. They are not intended to be exhaustive or to limit the present disclosure to the specific configurations as described. Accordingly, many modifications and variations will be apparent to those skilled in the art, and the general principles defined herein may be applied to other embodiments and applications without departing from the spirit and scope of the present disclosure. Additionally, the discussion of the preceding embodiments is not intended to limit the present disclosure. Thus, the present disclosure is not intended to be limited to the embodiments shown, but is to be accorded the widest scope consistent with the principles and features disclosed herein and defined by the claims appended hereto.

What is claimed is:

1. A high density opto-electronic interconnection arrangement comprising
a substrate formed to support a plurality of electrical signal paths, terminating as electrical surface contacts at defined locations on the substrate;
an interposer disposed over the substrate and formed to include a plurality of a through-vias that create an electrical connection to the electrical surface contacts of the substrate;
a plurality of electrical ICs mounted in flip-chip form on the interposer; and
a plurality of optical ICs mounted in flip-chip form on the plurality of electrical ICs to provide a one-to-one association between the plurality of electrical ICs and the plurality of optical ICs.

2. The high density opto-electronic interconnection arrangement as defined in claim 1 wherein at least one optical IC further comprises an optical fiber array connector formed along an edge of a top surface thereof.

3. The high density opto-electronic interconnection arrangement as defined in claim 2 wherein the at least one optical IC is disposed to overhang an edge of the associated electrical IC so as to expose the edge of the optical IC top surfaced including the optical fiber array connector.

4. The high density opto-electronic interconnection arrangement as defined in claim 1 wherein a plurality of high density copper pillar connections are used to provide electrical connections between the interposer and the plurality of electrical ICs.

5. The high density opto-electronic interconnection arrangement as defined in claim 1 wherein a plurality of high density copper pillar connections are used to provide electrical connections between each electrical IC and its associated optical IC.

6. The high density opto-electronic interconnection arrangement as defined in claim 1 wherein a plurality of high density micro-bump connections are used to provide electrical connections between the interposer and the plurality of electrical ICs.

7. The high density opto-electronic interconnection arrangement as defined in claim 1 wherein a plurality of high density micro-bump connections are used to provide electrical connections between each electrical IC and its associated optical IC.

8. The high density opto-electronic interconnection arrangement as defined in claim 1 wherein the interposer comprises a single layer of insulative material disposed over a top surface of the substrate, with the plurality of electrical ICs and the high performance IC disposed at predetermined locations on the interposer.

9. The high density opto-electronic interconnection arrangement as defined in claim 1 wherein the interposer comprises a plurality of individual layers of insulative material, associated with each plurality of electric ICs in a one-to-one relationship.

10. The high density opto-electronic interconnection arrangement as defined in claim 9 wherein a plurality of compliant layers are disposed between the individual interposer layers and the associated electrical IC.

11. The high density opto-electronic interconnection arrangement as defined in claim 1 wherein the interposer comprises silicon.

12. The high density opto-electronic interconnection arrangement as defined in claim 1 wherein the interposer comprises glass.

13. The high density opto-electronic interconnection arrangement as defined in claim 1 wherein the arrangement further comprises an array of electrical connections formed across a bottom surface of the substrate.

14. The high density opto-electronic interconnection arrangement as defined in claim 13 wherein the array of electrical connections comprises a ball grid array connection.
